(19) United States
(12) Patent Application Publication
(10) Pub. No.: US 2010/0103622 A1
(43) Pub. Date: Apr. 29, 2010

(54) ELECTRONIC CONTROL DEVICE

(75) Inventors: Hiroshi KATO, Nikko-shi (JP); Kyohei TAKEUCHI, Utsunomiya-shi (JP)

Correspondence Address: CANTOR COLBURN, LLP, 20 Church Street, 22nd Floor, Hartford, CT, 06103, US

(73) Assignee: KEIHIN CORPORATION, Tokyo (JP)

(21) Appl. No.: 12/604,126

(22) Filed: Oct. 22, 2009

(30) Foreign Application Priority Data
Oct. 24, 2008 (JP) 2008-274791
Oct. 24, 2008 (JP) 2008-274792

(51) Int. Cl. H05K 7/20

(52) U.S. Cl. 361/707

(57) ABSTRACT

The electronic control device includes: a printed circuit board; a heat-generating member having a plurality of legs which are mounted on the printed circuit board by connections between the legs and the printed circuit board; and a casing which radiates heat that is transferred from the heat-generating member, wherein: the legs are connected via press-fit connections with the printed circuit board.

### BACKGROUND OF THE INVENTION

1. Field of the Invention

The present invention relates to an electronic control device including a printed circuit board, and a heat-generating member which is mounted on the printed circuit board.

The present invention also relates to an electronic control device including a printed circuit board on which a heat-generating member is mounted, and a casing which accommodates the printed circuit board.

Priority is claimed on Japanese Patent Application No. 2008-274791, filed Oct. 24, 2008, and Japanese Patent Application No. 2008-274792, filed Oct. 24, 2008, the content of which are incorporated herein by reference.

2. Description of Related Art

Products such as four-wheel vehicles and two-wheel vehicles are often provided with an electronic control device which includes: a printed circuit board on which a heat-generating member, e.g., central processing unit (CPU) or a device driver is mounted; and a casing which accommodates the printed circuit board. The electronic control device performs electronic control of the devices installed in the four-wheel vehicles and two-wheel vehicles.

In such electronic control devices, heat generated from the heat-generating member needs to be transferred to the casing, and then radiated, in order for the heat-generating member to function satisfactory. This requirement further necessitates the members of the device to have highly precise dimensions, such members including the heat-generating member, the casing, and a heat transfer member, which is provided between the heat-generating member and the casing.

In addition, in such electronic control device, in order to obtain suitable operation condition for various members mounted on the printed circuit board, including the heat-generating member, the heat generated therefrom needs to be radiated to the outside.

In this regard, for example, Japanese Unexamined Patent Application, First Publication H10-190263 discloses a method in which the heat emerged from the heat-generating member is transferred to the casing, by providing a cylindrical protrusion that projects towards inside of the casing (sealed casing), at a part thereof, and by abutting the protrusion to the heat-generating member provided on the printed circuit board.

In addition, Japanese Unexamined Patent Application, First Publication 2006-86536 discloses a method in which a heat-generating member is connected to the casing (cover) via a heat radiating member, and heat emerged from the heat-generating member is transferred to the casing, through the heat radiating member (see, e.g. FIG. 6 of the aforementioned document).

In addition, two other documents, Japanese Unexamined Patent Application, First publication 2003-115681, and Japanese Unexamined Patent Application, First publication 2006-294754, disclose methods of transferring heat generated from the heat-generating member to the casing, by providing an opening (through-hole) on a printed circuit board in a region on which the heat-generating member is mounted. The method further provides a cylindrical protrusion that projects towards inside of the casing, at a part thereof. The aforementioned heat transfer is performed by abutting the protrusion to the heat-generating member, either directly or via a heat sink.

### SUMMARY OF THE INVENTION

However, due to the change in manufacture environment over time, it is difficult to constantly realize highly precise dimensions of the members, as required in the method mentioned above.

Therefore, in the related electronic control device, when performing the processes of, e.g., mounting the heat-generating member on the printed circuit board, or manufacturing the casing, a certain degree of errors in dimensions of the members are permitted. When the electronic control device is assembled, the printed circuit board and the casing are pressed down and forced together and assembled, and thus the errors in dimensions are absorbed.

In such cases, although the preciseness in dimensions of the resulting assembled electronic control device as a whole can be obtained, the heat-generating member and the connection part of the heat-generating member and the printed circuit board receive stress, possibly resulting in damages of the electronic control device.

An aspect of the present invention is achieved in view of the aforementioned problems; and a first object thereof is to reduce stress exerted on the connection part of the heat-generating member or the heat-generating member and the printed circuit board.

Moreover, as in the case for the aforementioned related documents, in a constitution where either a part of the casing, a radiating member fixed on the casing, or a heat sink fixed on the casing abuts on the heat-generating member, during the assembly of the electronic control device, the heat-generating member is pressed by either the casing, radiating member, or the heat sink, resulting in stress on the heat-generating member.

Moreover, in a constitution in which a part of the casing abuts directly on the heat-generating member, in order to reduce the stress on the heat-generating member, and to obtain an efficient heat transfer, the part of the casing needs to precisely abut on the heat-generating member. Accordingly, the components of the electronic control device are required to have highly precise dimensions.

Another aspect of the present invention is achieved in view of the aforementioned problems; and a second object thereof is, in an electronic control device, to enable radiation of heat that is generated from a heat-generating member to outside, and at the same time, to reduce stress exerted on the heat-generating member, and also to safely lower the required preciseness degree of the dimensions of individual constitutional members of the electronic control device.

Aspects of the present invention employ the following constitutions and achieve the aforementioned first object.

A first aspect of the present invention employs an electronic control device including: a printed circuit board; a heat-generating member having a plurality of legs which are mounted on the printed circuit board by connections between the legs and the printed circuit board; and a casing which radiates heat that is transferred from the heat-generating member, wherein: the legs are connected via press-fit connections with the printed circuit board.

A second aspect of the present invention employs the constitution of the aforementioned first aspect, wherein at least one of the legs is a lead that electrically connects the heat-generating member and the printed circuit board.

A third aspect of the present invention employs either of the aforementioned first or the second aspect, wherein at least one of the legs is a dummy lead that connects the heat-generating member and the printed circuit board without an electric connection.

A fourth aspect of the present invention employs either of the aforementioned first to the third aspect, which further includes a heat transfer member that transfers heat generated from the heat-generating member to the casing.

A fifth aspect of the present invention employs either of the aforementioned first to the fourth aspect, wherein the legs are connected via press-fit connections with the printed circuit board and with the casing.

According to the invention of the first to fifth aspects, legs of the heat-generating member that is mounted on the printed circuit board are connected with the printed circuit board via press-fit connections. Accordingly, the heat-generating member may be repositioned in the thickness direction of the printed circuit board, i.e., the height direction of the heat-generating member.

That is, according to the aforementioned aspects of the present invention, the position of the heat-generating member with respect to the printed circuit board in the height direction may be arbitrarily adjusted. Accordingly, even when the dimensional preciseness of the constituent members of the electronic control device is not satisfactory, the heat-generating member may be provided at the most suitable position.

Furthermore, even in cases where force is exerted on the heat-generating member in the height direction, during the assembly of the electronic control device, since the leg is press-fit connected with the printed circuit board, the heat-generating member may be repositioned in the height direction with respect to the printed circuit board, with respect to the exerted force. Accordingly, the stress exerted on the heat-generating member or the connection part of the heat-generating member and the printed circuit board may be reduced.

Therefore, according to the aforementioned aspects of the present invention, in the electronic control device, the stress exerted on the heat-generating member itself or the connection part of the heat-generating member and the printed circuit board may be preferably reduced.

Moreover, other aspects of the present invention employ the following constitutions and achieve the aforementioned second object.

A sixth aspect of the present invention employs an electronic control device including: a printed circuit board on which a heat-generating member is mounted; a casing that accommodates the printed circuit board; and a press-fit member having a heat-generating member contact region that contacts with the heat-generating member, and a casing contact region that contacts with the casing, wherein: the press-fit member is press-fit connected with either the printed circuit board or the casing; and the press-fit member transfers heat generated from the heat-generating member.

A seventh aspect of the present invention employs the constitution of the aforementioned sixth aspect, wherein: the press-fit member has a first end and a second end that are press-fit connected to the printed circuit board or the casing; and the heat-generating member contact region and the casing contact region are provided between the first end and the second end.

An eighth aspect of the present invention employs either of the constitution of the aforementioned sixth or seventh aspect, wherein the heat-generating member contact region contacts with the heat-generating member via a heat transfer member.

A ninth aspect of the present invention employs either of the constitution of the aforementioned sixth to eighth aspect, wherein the casing contact region contacts with the casing via a heat transfer member.

A tenth aspect of the present invention employs either of the constitution of the aforementioned sixth to ninth aspect, wherein the heat-generating member contact region contacts with the heat-generating member along the entire width of the heat-generating member.

In the present specification, the term ‘contact’ means not only direct contact state of one object with another object, but also includes indirect contact state of one object with another object via a third object.

According to the invention of above-mentioned sixth to tenth aspect, the heat generated in the heat-generating member is transferred to the casing, by the press-fit member. Accordingly, the heat generated from the heat-generating member may be radiated to the outside.

Moreover, the press-fit member is press-fit connected with either the printed circuit board or with the casing. Accordingly, the press-fit member may be repositioned along the connection direction with respect to the printed circuit board or the casing.

That is, according to the aforementioned aspects of the present invention, the position of the press-fit member along the connection direction may be arbitrarily adjusted, and thereby the press-fit member, which transfers heat, may be securely positioned to make required contact with the heat-generating member and the casing. Accordingly, even when the dimensional preciseness of the constituent members of the electronic control device is not satisfactory, the heat generated from the electronic control device may be securely transferred to the casing. Accordingly, the required degree of preciseness of the dimensions of individual constitutional members of the electronic control device may be safely lowered.

Moreover, during the assembly of the electronic control device, even when force is exerted on the press-fit member in the connection direction, since the press-fit member is press-fit connected with the printed circuit board or the casing, the press-fit member may be repositioned according to the force exerted thereon, thereby stress exerted on the heat-generating member can be reduced.

Therefore, according to the present invention, in the electronic control device, the heat generated in the heat-generating member may be radiated to the outside, and, at the same time, the stress exerted on the heat-generating member can be reduced, and also the required degree of preciseness in dimensions of each constituent member may be safely lowered.

### BRIEF DESCRIPTION OF THE DRAWINGS

FIG. 1 is a schematic sectional view showing a part of an electronic control device according to a first embodiment of the present invention.

FIG. 2 is an enlarged sectional view of a leg of a heat-generating member provided in the electronic control device according to the first embodiment of the present invention.

FIG. 3 is a sectional view showing a modified example of the electronic control device according to the first embodiment of the present invention, having a constitution in which a protrusion is provided above the heat-generating member.

FIG. 4 is a sectional view showing a modified example of the electronic control device according to the first embodiment of the present invention, having a constitution in which a protrusion is provided below the heat-generating member.

FIG. 5 is a sectional view showing a modified example of the electronic control device according to the first embodiment of the present invention, having a constitution in which a protrusion provided above the heat-generating member, and having a soft heat transfer member provided between the protrusion and the heat-generating member.

FIG. 6 is a sectional view showing a modified example of the electronic control device according to the first embodiment of the present invention, having a constitution in which a protrusion provided below the heat-generating member, and having a soft heat transfer member provided between the protrusion and the heat-generating member.

FIG. 7 is a sectional view showing a modified example of the electronic control device according to the first embodiment of the present invention, having a constitution in which a solid heat transfer member is provided between the heat-generating member and the upper casing.

FIG. 8 is a sectional view showing a modified example of the electronic control device according to the first embodiment of the present invention, having a constitution in which a solid heat transfer member is provided between the heat-generating member and the lower casing.

FIG. 9 is a sectional view showing a modified example of the electronic control device according to the first embodiment of the present invention, having a constitution in which a solid heat transfer member is provided between the heat-generating member and the upper casing, and in which a soft heat transfer member is further provided between the solid heat transfer member and the heat-generating member.

FIG. 10 is a sectional view showing a modified example of the electronic control device according to the first embodiment of the present invention, having a constitution in which a solid heat transfer member is provided between the heat-generating member and the lower casing, and in which a soft heat transfer member is further provided between the solid heat transfer member and the heat-generating member.

FIG. 11 is a sectional view schematically showing a part of an electronic control device according to a second embodiment of the present invention.

FIG. 12 is a sectional view showing a modified example of the electronic control device according to the second embodiment of the present invention, having a constitution that is provided with a protrusion above the heat-generating member.

FIG. 13 is a sectional view showing a modified example of the electronic control device according to the second embodiment of the present invention, having a constitution that is provided with a protrusion below the heat-generating member.

FIG. 14 is a sectional view showing a modified example of the electronic control device according to the second embodiment of the present invention, having a constitution that is provided with a protrusion above the heat-generating member, and a soft heat transfer member is provided between the protrusion and the heat-generating member.

FIG. 15 is a sectional view showing a modified example of the electronic control device according to the second embodiment of the present invention. The constitution is provided with a protrusion below the heat-generating member, and a soft heat transfer member provided between the protrusion and the heat-generating member.

FIG. 16 is a sectional view showing a modified example of the electronic control device according to the second embodiment of the present invention. The constitution is provided with a solid heat transfer member that is positioned between the heat-generating member and the upper casing.

FIG. 17 is a sectional view showing a modified example of the electronic control device according to the second embodiment of the present invention. The constitution is provided with a solid heat transfer member that is positioned between the heat-generating member and the lower casing.

FIG. 18 is a sectional view showing a modified example of the electronic control device according to the second embodiment of the present invention. The constitution is provided with a solid heat transfer member that is positioned between the heat-generating member and the upper casing. Moreover, a soft heat transfer member is provided between a solid heat transfer member and a heat-generating member.

FIG. 19 is a sectional view showing a modified example of the electronic control device according to the second embodiment of the present invention. The constitution is provided with a solid heat transfer member that is positioned between the heat-generating member and the lower casing. Moreover, a soft heat transfer member is provided between a solid heat transfer member and a heat-generating member.

FIG. 20 is a sectional view schematically showing a part of an electronic control device according to a third embodiment of the present invention.

FIG. 21 is an enlarged perspective view of a press-fit bus-bar that is provided to the electronic control device according to the third embodiment of the present invention.

FIG. 22 is an enlarged sectional view of a contact part provided to the press-fit bus-bar that is provided to the electronic control device according to a third embodiment of the present invention.

FIG. 23 is a sectional view of a modified example of the electronic control device according to the third embodiment of the present invention, showing a constitution in which: a heat-generating member contact region comes into a contact with a heat-generating member via a soft heat transfer member; and a casing contact region comes into a contact with a casing via the soft heat transfer member.

FIG. 24 is a sectional view of a modified example of the electronic control device according to the third embodiment of the present invention, showing a constitution in which: an opening is provided at a printed circuit board; a part of the press-fit bus-bar is inserted through the opening; and the heat-generating member contact region comes into contact with the heat-generating member from a side thereof that is facing the printed circuit board.

FIG. 25 is a sectional view of a modified example of the electronic control device according to the third embodiment of the present invention, showing a constitution in which, in addition to the constitution shown in FIG. 24: the heat-generating member contact region comes into a contact with the heat-generating member via the soft heat transfer member; and the casing contact region comes into a contact with the casing via the soft heat transfer member.

FIG. 26 is a sectional view of a modified example of the electronic control device according to the third embodiment of the present invention, showing a constitution in which: a printed circuit board heat transfer passage is provided; and the heat-generating member contact region of the press-fit bus-bar comes into contact with the printed circuit board on a surface that is opposite to the surface on which the heat-generating member is mounted.

FIG. 27 is a sectional view schematically showing a part of the electronic control device according to a fourth embodiment of the present invention.

FIG. 28 is a sectional view of a modified example of the electronic control device according to the fourth embodiment of the present invention, showing a constitution in which: a heat-generating member contact region comes in contact with a heat-generating member via a soft heat transfer member; and a casing contact region comes in contact with a casing via the soft heat transfer member.

FIG. 29 is a sectional view of a modified example of the electronic control device according to the fourth embodiment of the present invention, showing a constitution in which: an opening is provided at a printed circuit board; a part of the press-fit bus-bar is inserted through the opening; and the heat-generating member contact region comes into contact with the heat-generating member from a side thereof that is facing the printed circuit board.

FIG. 30 is a sectional view of a modified example of the electronic control device according to the fourth embodiment of the present invention, showing a constitution in which, in addition to the constitution shown in FIG. 29: the heat-generating member contact region comes in contact with the heat-generating member via the soft heat transfer member; and the casing contact region comes in contact with the casing via the soft heat transfer member.

FIG. 31 is a sectional view of a modified example of the electronic control device according to the fourth embodiment of the present invention, showing a constitution in which, a printed circuit board heat transfer passage is provided; and the heat-generating member contact region of the press-fit bus-bar comes into contact with the printed circuit board on a surface that is opposite to the surface on which the heat-generating member is mounted.

### DETAILED DESCRIPTION OF THE INVENTION

Hereinafter, an embodiment of an electronic control device according to the present invention is explained with reference to the attached figures. In the figures, the scaling of the components is appropriately adjusted so that the components are shown in sufficiently recognizable sizes.

### First Embodiment

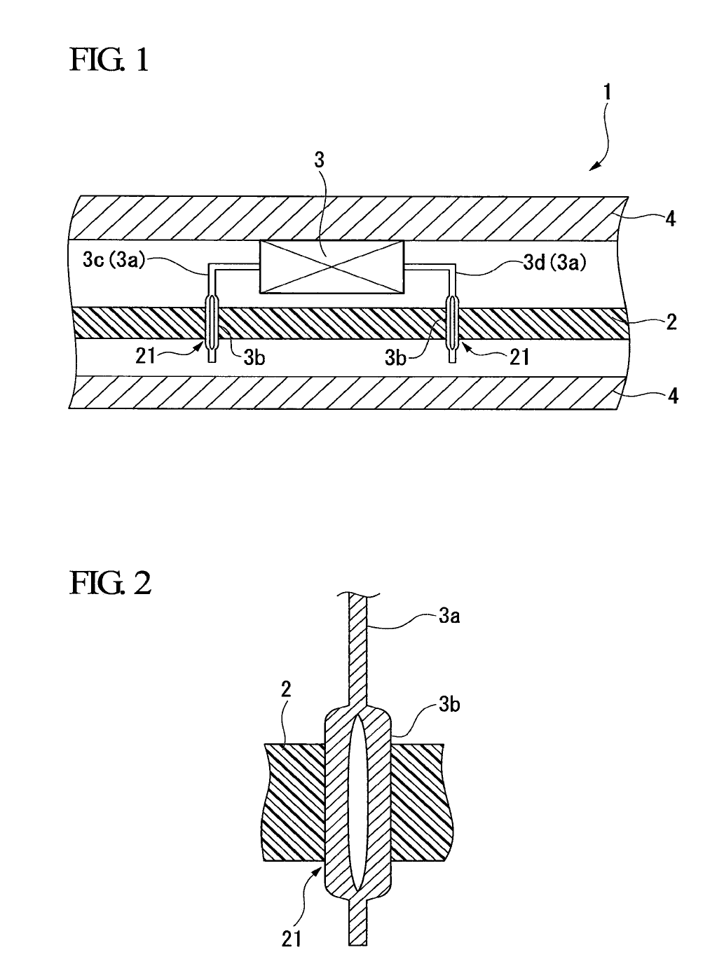

FIG. 1 is a schematic sectional view showing a part of an electronic control device 1 according to the present embodiment. As shown in this figure, the electronic control device 1 is provided with: a printed circuit board 2; a heat-generating member 3; and a casing 4.

The printed circuit board 2 is a multilayered circuit board on which one or more circuit patterns are provided, and on which a plurality of electronic members are mounted, including a central processing unit (CPU) or a device driver, or the like.

Moreover, the printed circuit board 2 is provided with a plurality of through holes 21, on which legs 3a of the heat-generating member 3 may be installed.

As mentioned above, the heat-generating member 3 is a kind of electronic part such as a central processing unit (CPU) or a device driver that generates heat when provided with electricity. The heat-generating member 3 is mounted on the printed circuit board 2 by connections of a plurality of legs 3a to the printed circuit board 2.

In the electronic control device 1 of the present embodiment, every each of the legs 3a of the heat-generating member 3 has a connection part 3b, as shown in the enlarged view of FIG. 2, which provides a press-fit connection with the printed circuit board 2. This connection part 3b is constituted wider than other parts of the leg 3a, and has a capacity of expanding and contracting in the radius direction thereof. The legs 3a are connected to the printed circuit board 2 by press-fitting of each of the connection parts 3b into through hole 21.

As such, since the legs 3a are press-fit connected to the printed circuit board 2, the heat-generating member 3 can be moved or repositioned along the thickness direction of the printed circuit board 2, by applying force from the height direction. Thereby, this constitution allows position adjustments of the heat-generating member 3 with respect to the printed circuit board 2. The connection part 3b has a length longer than the thickness of the printed circuit board 2, in order for the heat-generating member 3 to maintain a preferable range of position adjustment capacity with respect to the printed circuit board 2.

Although in FIG. 2, the connection part 3b is shown in a so-called eyelet-shape, other constitutions such as sigma-shape, M-shape, ring, or circle shape may also be used.

The legs 3a of the heat-generating member 3 are constituted including: one or more of legs 3c that functions as a lead that performs an electric connection between the heat-generating member 3 and the printed circuit board 2; and one or more of legs 3d that functions as a dummy lead that may physically connect the heat-generating member 3 and the printed circuit board 2 without electrically connecting them.

The casing 4 accommodates inside thereof the printed circuit board 2, and has a supporting member (not shown) that fixes the relative position of the casing 4 and the printed circuit board 2.

The aforementioned supporting member supports the printed circuit board 2, and thereby, the heat-generating member 3 mounted on the printed circuit board 2 and the internal wall surface of the casing 4 are abutted together.

The casing 4 may be made of metal material such as zinc, aluminum, or copper, and formed by processes such as press forming, cutting, or die-casting.

With the aforementioned constitution, in the electronic control device 1, the heat generated from the heat-generating member 3 is transferred to the casing 4 via the legs 3a, and radiated to outside.

In the aforementioned electronic control device 1 according to the present embodiment, the legs 3a of the heat-generating member 3 that is mounted to the printed circuit board 2 are press-fit connected to the printed circuit board 2. Accordingly, the heat-generating member 3 can be repositioned in the thickness direction of the printed circuit board 2, i.e., the height direction of the heat-generating member.

In other words, in the electronic control device 1 according to the present embodiment, the positioning in the height direction of the heat-generating member 3 with respect to the printed circuit board 2 can be arbitrarily adjusted. Thereby, even when the preciseness in dimensions of the constituent members of the electronic control device 1, such as casing 4 or the like, is not sufficiently high, heat-generating member 3 can be positioned within the most preferable range.

Moreover, during the assembly of the electronic control device 1, even when force is exerted on the heat-generating member 3 from the height direction, since the legs 3a are press-fit connected to the printed circuit board 2, the heat-generating member 3 can be repositioned with respect to the printed circuit board 2 in the height direction, in response to the exerted force. Thereby, a stress exertion to the heat-generating member 3 and the connection part of the heat-generating member 3 and the printed circuit board 2 can be prevented.

Accordingly, in the electronic control device 1 according to the present embodiment, the stress amount exerted on the heat-generating member 3 and the connection part between the heat-generating member 3 and the printed circuit board 2 can be reduced.

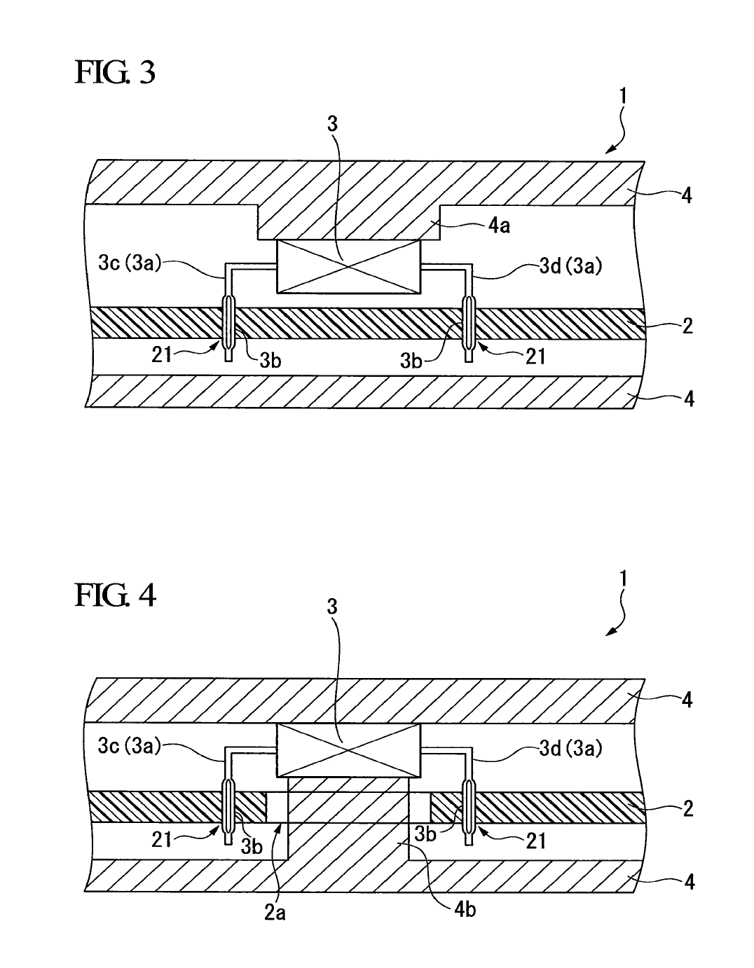

In the electronic control device 1 according to the present embodiment, as shown in FIG. 3, a protrusion 4a that protrudes from a part of the casing 4 positioned above the heat-generating member 3 may be provided. The protrusion 4a may abut on the heat-generating member 3.

By adopting aforementioned constitution, even when the distance from the casing 4 to the mounting surface of the printed circuit board 2 is significantly long, the heat-generating member 3 can be directly abutted on the casing 4.

Moreover, in the electronic control device 1 according to the present embodiment, as shown in FIG. 4, an opening 2a positioned in a region of the printed circuit board 2 below the heat-generating member 3 may be provided. In addition, a protrusion 4b protruding from a part of the casing 4 positioned below the heat-generating member 3 may also be provided thereto. Furthermore, the protrusion 4b may be inserted through the opening 2a, and abutted on the heat-generating member 3.

By adopting aforementioned constitution, as in the case for the previous constitution, even when the distance from the casing 4 to the mounting surface of the printed circuit board 2 is significantly long, the heat-generating member 3 can be directly abutted on the casing 4.

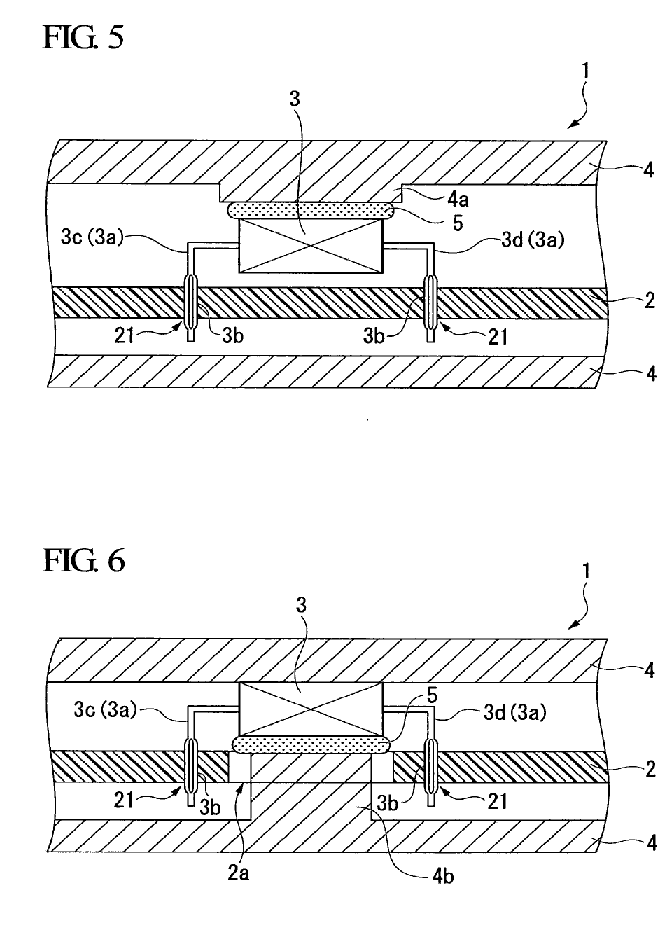

Moreover, in the electronic control device 1 according to the present embodiment, as in the constitution shown in FIG. 5, between the protrusion 4a shown in FIG. 3 and the heat-generating member 3, a soft heat transfer member 5 such as silicon gel, grease, or heat transfer sheet may be provided.

By adopting such constitution, since the heat-generating member 3 is connected with the casing 4 through the soft heat transfer member 5, force exerted from the casing 4 to the heat-generating member 3 can be absorbed by the deformation of the soft heat transfer member 5, and thereby the stress on the heat-generating member 3 can be further reduced.

Moreover, in the electronic control device 1 according to the present embodiment, as shown in FIG. 6, between the protrusion 4b shown in FIG. 4 and the heat-generating member 3, a soft heat transfer member 5 such as silicon gel, grease, or heat transfer sheet may be provided.

By adopting such constitution, as in the case for the previous constitution, since the heat-generating member 3 is connected with the casing 4 through the soft heat transfer member 5, force exerted from the casing 4 to the heat-generating member 3 can be absorbed by the deformation of the soft heat transfer member 5, and thereby the stress on the heat-generating member 3 can be further reduced.

In addition, as an alternative constitution, the soft heat transfer member as shown in FIGS. 5 and 6 may also be provided between a casing 4 that does not include protrusions 4a and 4b and the heat-generating member 3.

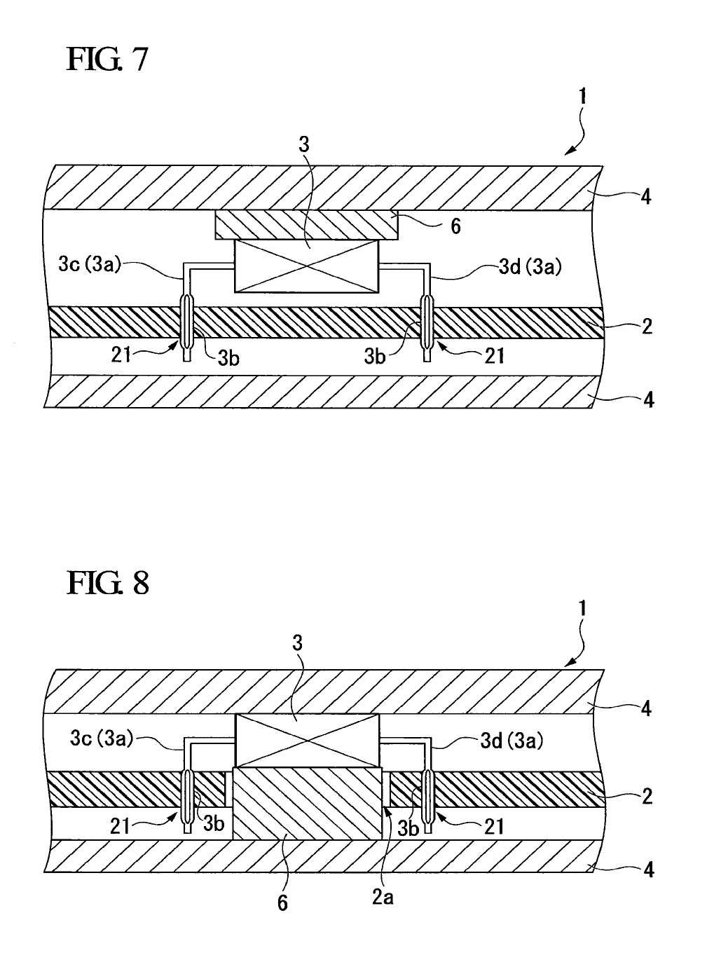

Moreover, in the electronic control device 1 according to the present embodiment, as shown in FIG. 7, a solid heat transfer member 6 made of metal having a high thermal conductivity, such as copper, stainless steel, may also be provided between the heat-generating member 3 and a region of the casing 4 positioned above the heat-generating member 3.

By adopting such constitution, heat generated from the heat-generating member 3 can be absorbed rapidly by the heat transfer member 6. Thereby, a further efficient radiation can be performed.

Moreover, since the solid heat transfer member 6 may readily be provided at any arbitral positions, as compared with the case where the protrusions 4a and 4b are provided on the casing 4, the abovementioned constitution can more easily adopt to device design changes such as changes in the layouts of the heat-generating member 3 on the printed circuit board 2.

Moreover, in the electronic control device 1 according to the present embodiment, as shown in FIG. 8: an opening 2a may be provided in a region of the printed circuit board 2 positioned below the heat-generating member 3; the protrusion 4b may be inserted through the opening 2a, and a solid heat transfer member 6 may be provided between the heat-generating member 3 and a region of the casing 4 positioned below the heat-generating member 3.

By adopting such constitution, as in the case for the previous constitution, heat generated from the heat-generating member 3 can be absorbed rapidly by the heat transfer member 6. Thereby, a further efficient radiation can be performed.

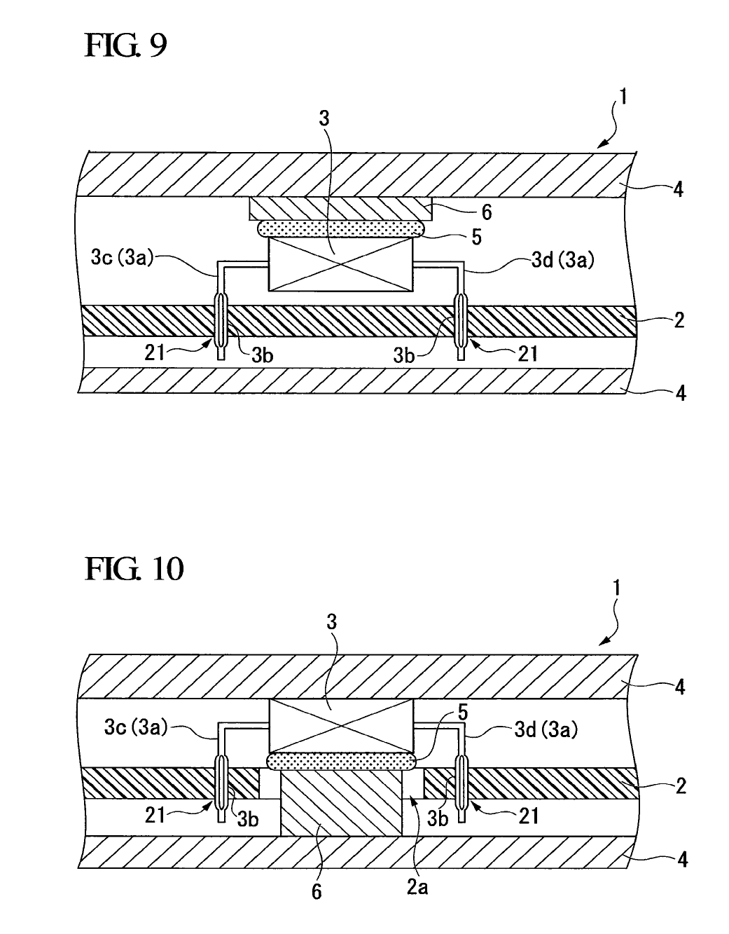

Moreover, in the electronic control device 1 according to the present embodiment, as shown in FIGS. 9 and 10, the soft heat transfer member 5 may be provided between the solid heat transfer member 6 as shown in FIGS. 7 and 8 and the heat-generating member 3.

### Second Embodiment

Next, a second embodiment according to the present invention is explained. In the explanation of the second embodiment, portions that have similar constitutions with the first embodiment will be omitted or simplified.

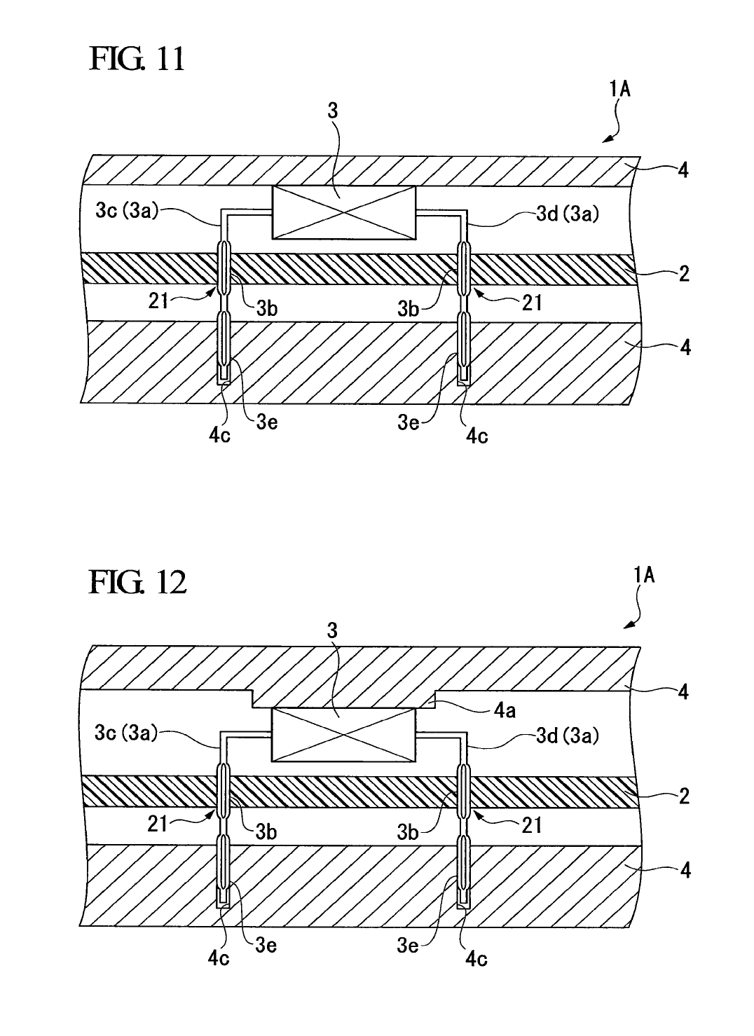

FIG. 11 is a sectional view schematically showing a part of electronic control device 1A according to the present embodiment. As shown in this figure, the legs 3a of the heat-generating member 3 provided to the electronic control device 1A according to the present embodiment extend further downward as compared to the legs 3a in the aforementioned first embodiment and press-fit connected also with the casing 4.

That is, in the electronic control device 1A according to the present embodiment, the legs 3a of the heat-generating member 3 is press-fit connected with both the printed circuit board 2 and the casing 4.

More particularly, in addition to the connection part 3b, another connection part 3e, that is press-fit connected with the casing 4, is provided to the legs 3a. This connection part 3e is constituted to have broader width than the other parts of the leg 3a, and is capable of has a capacity of expanding and contracting in the radius direction thereof.

To the electronic control device 1A according to the present embodiment, an insertion hole 4c is provided. The connection part 3e is press-inserted into the insertion hole 4c, and thereby the legs 3a are press-fit connected to the casing 4.

In the electronic control device 1A according to the present embodiment having the aforementioned constitution, as compared to the constitution only including the connection part 3b, i.e., to the constitution in which the legs 3a are press-fit connected only with the printed circuit board 2, the legs 3a can further securely be fixed, and thereby an unintended reposition or movement of the heat-generating member 3 can be prevented.

In the electronic control device 1A according to the present embodiment, as shown in FIG. 12, a protrusion 4a may be provided that protrudes from a part of the casing 4 positioned above the heat-generating member 3. The protrusion 4a may be abutted on the heat-generating member 3.

By adopting aforementioned constitution, even when the distance from the casing 4 to the mounting surface of the printed circuit board 2 is significantly long, the heat-generating member 3 can be directly abutted on the casing 4.

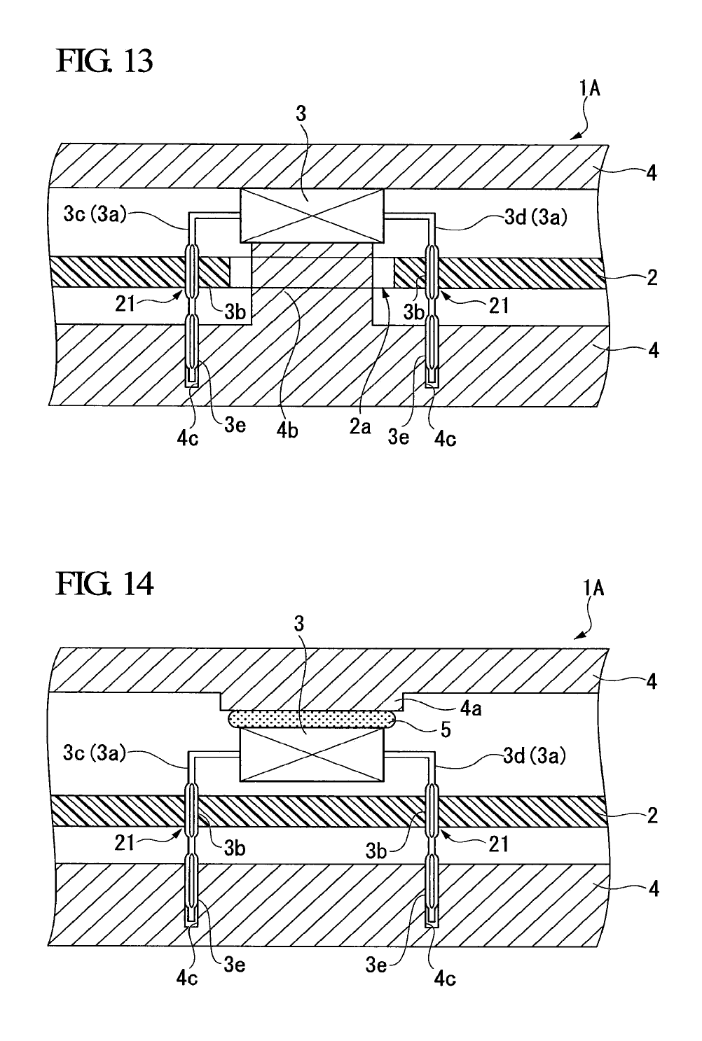

Moreover, in the electronic control device 1A according to the present embodiment, as shown in FIG. 13, an opening 2a may be provided in a region of the printed circuit board 2 positioned below the heat-generating member 3. In addition, a protrusion 4b may be provided, protruding from a part of the casing 4 positioned below the heat-generating member 3. The protrusion 4b may then be inserted through the opening 2a, and then abutted on the heat-generating member 3.

By adopting aforementioned constitution, as in the case for the previous constitution, even when the distance from the casing 4 to the mounting surface of the printed circuit board 2 is significantly long, the heat-generating member 3 can be directly abutted on the casing 4.

Moreover, in the electronic control device 1A according to the present embodiment, as shown in FIG. 14, between the protrusion 4a shown in FIG. 12 and the heat-generating member 3, a soft heat transfer member 5 such as silicon gel, grease, or heat transfer sheet may be provided.

By adopting such constitution, since the heat-generating member 3 is connected with the casing 4 through the soft heat transfer member 5, force exerted from the casing 4 to the heat-generating member 3 can be absorbed by the deformation of the soft heat transfer member 5, and thereby the stress on the heat-generating member 3 can be further reduced.

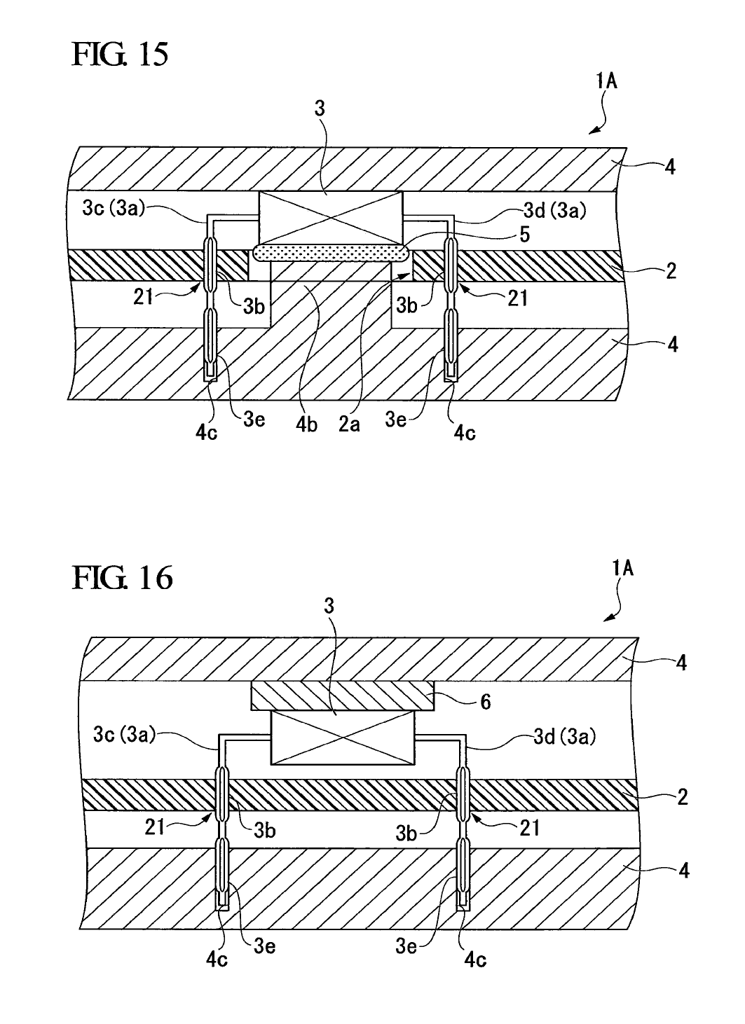

Moreover, in the electronic control device 1A according to the present embodiment, as shown in FIG. 15, between the protrusion 4b shown in FIG. 13 and the heat-generating member 3, a soft heat transfer member 5 such as silicon gel, grease, or heat transfer sheet may be provided.

By adopting such constitution, as in the case for the previous constitution, since the heat-generating member 3 is connected with the casing 4 through the soft heat transfer member 5, force exerted from the casing 4 to the heat-generating member 3 can be absorbed by the deformation of the soft heat transfer member 5, and thereby the stress on the heat-generating member 3 can be further reduced.

In addition, as an alternative constitution, the soft heat transfer member as shown in FIGS. 14 and 15 may also be provided between a casing 4 that does not include protrusions 4a and 4b and the heat-generating member 3.

Moreover, in the electronic control device 1A according to the present embodiment, as shown in FIG. 16, a solid heat transfer member 6 made of metal having a high thermal conductivity, such as copper, or aluminum, may also be provided between the heat-generating member 3 and a region of the casing 4 positioned above the heat-generating member 3.

By adopting such constitution, the heat generated from the heat-generating member 3 can rapidly absorbed by the heat transfer member 6, and a more efficient heat radiation can be achieved.

Moreover, since the solid heat transfer member 6 may readily be provided at any arbitral positions, as compared with the case where the protrusions 4a and 4b are provided on the casing 4, the abovementioned constitution can more easily adopt to device design changes such as changes in the layouts of the heat-generating member 3 on the printed circuit board 2.

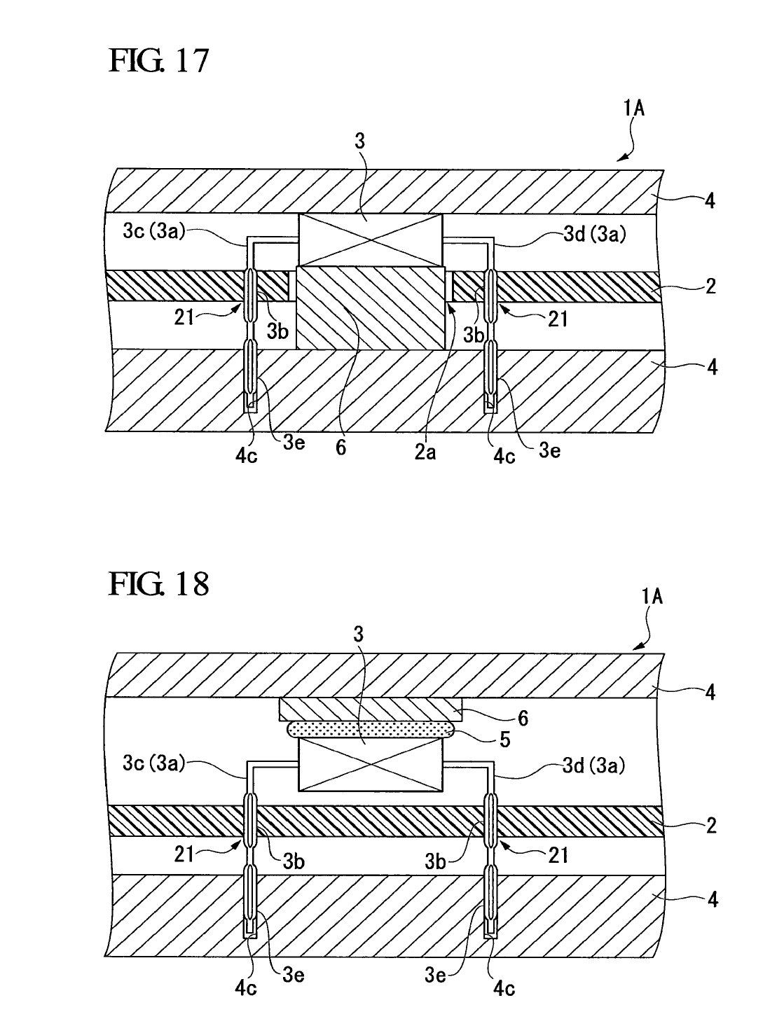

Moreover, in the electronic control device 1A according to the present embodiment, as shown in FIG. 17, an opening 2a may be provided in a region of the printed circuit board 2 positioned below the heat-generating member 3. The protrusion 4b may be inserted through the opening 2a. A solid heat transfer member 6 may be provided between the heat-generating member 3 and the region of the casing 4 positioned below the heat-generating member 3.

By adopting such constitution, as in the case for the previous constitution, heat generated from the heat-generating member 3 can be absorbed rapidly by the heat transfer member 6. Thereby, a further efficient radiation can be performed.

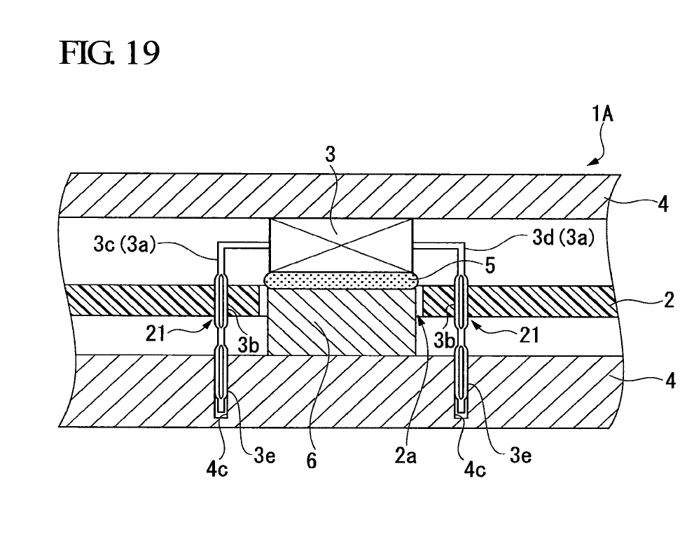

Moreover, in the electronic control device 1A according to the present embodiment, as shown in FIGS. 18 and 19, a soft heat transfer member 5 may be provided between the solid heat transfer member 6 as shown in FIGS. 16, 17 and the heat-generating member 3.

The preferable embodiments of the electronic control device according to the present invention are explained hereinabove, with reference to the attached figures. However, the scope of the present invention is not limited by the aforementioned embodiments. The constitutions and the combinations of the constituent members shown in each of the aforementioned embodiments are presented as examples, and the constitutions can be modified within the range not exceeding the essence of the present invention, various modifications are possible, in view of the design requirements and the like.

For example, in the constitutions of the aforementioned embodiments, the legs 3a are press-fit connected with the printed circuit board 2, or with both of the printed circuit board 2 and the casing 4.

However, the present invention is not limited thereto, but the legs 3a may have a function of urging the heat-generating member 3 toward the casing 4, so long as the amount of stress exerted does not exceed an acceptable value.

By adopting such constitution, the heat-generating member 3 can be constitutively abutted on the casing 4 or the heat transfer member 5, 6, and thereby, a reliable radiation can be achieved.

Hereinafter, another embodiment of an electronic control device according to the present invention is explained with reference to the attached figures. In the figures, the scaling of the components is appropriately adjusted so that the components are shown in sufficiently recognizable sizes.

### Third Embodiment

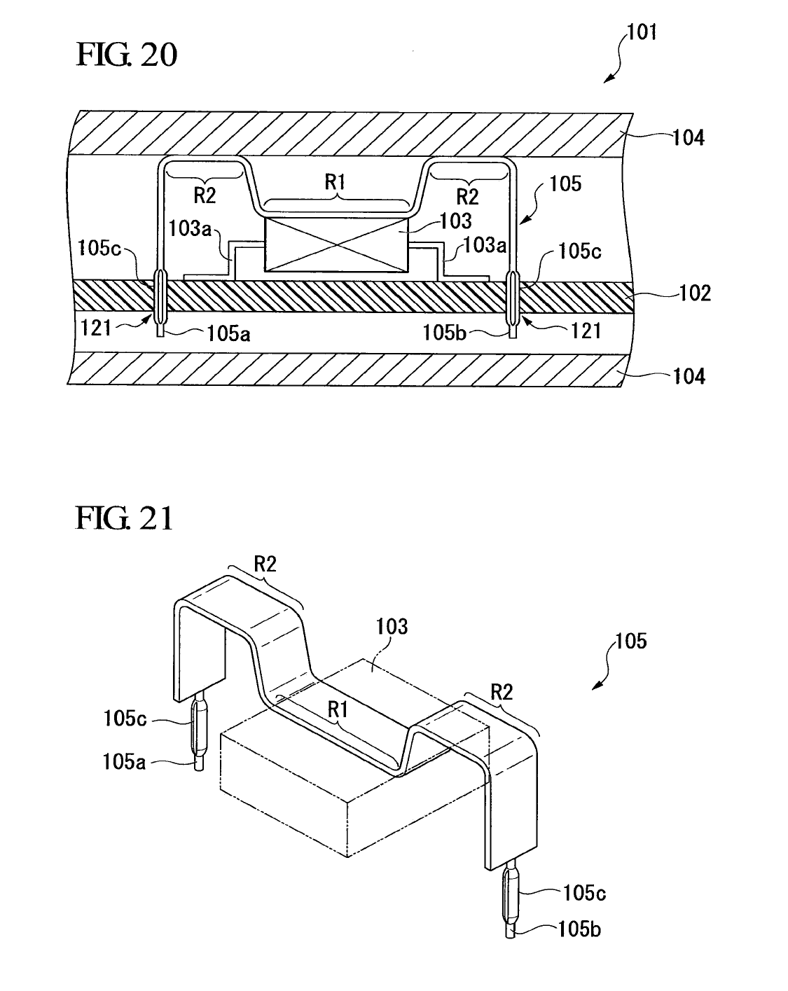

FIG. 20 is a sectional view schematically showing a part of the electronic control device 101 according to the present embodiment. As shown in this figure, the electronic control device 101 includes: a printed circuit board 102, a heat-generating member 103; a casing 104; and a press-fit bus-bar 105 (press-fit member).

The printed circuit board 102 is a multilayered circuit board on which one or more circuit patterns are provided, and on which a plurality of electronic members are mounted, including a central processing unit (CPU) or a device driver, or the like.

Moreover, the printed circuit board 102 is provided with a plurality of through holes 121, to which press-fit bus-bars 105 may be installed.

As mentioned above, the heat-generating member 103 is a kind of electronic part such as a central processing unit (CPU) or a device driver that generates heat when provided with electricity. The heat-generating member 103 is connected electrically and physically with the printed circuit board 102 via a plurality of leads 103a.

The casing 104 accommodates therein the printed circuit board 102, and is provided with a supporting member (not shown) that fixes the positional relationship of the casing 104 and the printed circuit board 102.

By the function of the support to the printed circuit board 102 by the aforementioned supporting member, the components-mounting surface (both upper and lower sides) of the printed circuit board 102 and the casing 104 are held with a predetermined distance.

The casing 4 may be made of metal material such as zinc, aluminum, or copper, and formed by processes such as press forming, cutting, or die-casting.

The electronic control device 101 according to the present embodiment includes a press-fit bus-bar 105. The heat transferred from the heat-generating member 103 to the printed circuit board 102 is further transferred by the press-fit bus-bar 105 from the printed circuit board 102 to the casing 104.

The press-fit bus-bar 105 is constituted with metal having a high thermal conductivity, such as copper and stainless steel. As shown in the enlarged perspective view of FIG. 21, a connection part 105c for press-fit connection with the printed circuit board 102 is provided at each of one end 105a (first end) and another end 105b (second end). This connection part 105c is constituted to have a width slightly wider than the through hole 121 of the printed circuit board 102, and has a capacity of expanding and contracting in the radius direction thereof. The press-fit bus-bar 105 is press-fit connected with the printed circuit board 102, by the connection part 105c being inserted into a through hole 121 of the printed circuit board 102.

Moreover, the press-fit bus-bar 105 has one or more bends between the one end 105a and the another end 105b. A heat-generating member contact region R1 that contacts with the heat-generating member 103 and a casing contact region R2 that contacts with the casing 104 are provided between the one end 105a and the another end 105b. In the electronic control device 101 according to the present embodiment, the press-fit bus-bar 105 has one heat-generating member contact region R1 provided in the center region of the press-fit bus-bar 105, and two casing contact regions R2 that are provided at the both sides with respect to the heat-generating member contact region R1.

The distance in the height direction from the heat-generating member contact region R1 to the casing contact region R2 of the press-fit bus-bar 105 in a state wherein the press-fit bus-bar 105 is not installed between the heat-generating member 103 and the casing 104 is preferably slightly longer than the distance between the heat-generating member 103 and the casing 104, so that the heat-generating member contact region R1 securely contacts with the heat-generating member 103 and that the casing contact region R2 securely contacts with the casing 104. In this case, the press-fit bus-bar 105 is constituted to possess plasticity so that it does not exert stress on the heat-generating member 103 and the casing 104, when the press-fit bus-bar 105 is installed between the heat-generating member 103 and the casing 104.

Moreover, as shown in FIG. 21, the heat-generating member contact region R1 contacts with the heat-generating member 103 along the entire width of the heat-generating member 103.

It is also preferable that the press-fit bus-bar 105 is constituted to have a sufficient width, so that the entire upper surface of the heat-generating member 103 is contacted by the heat-generating member contact region R1.

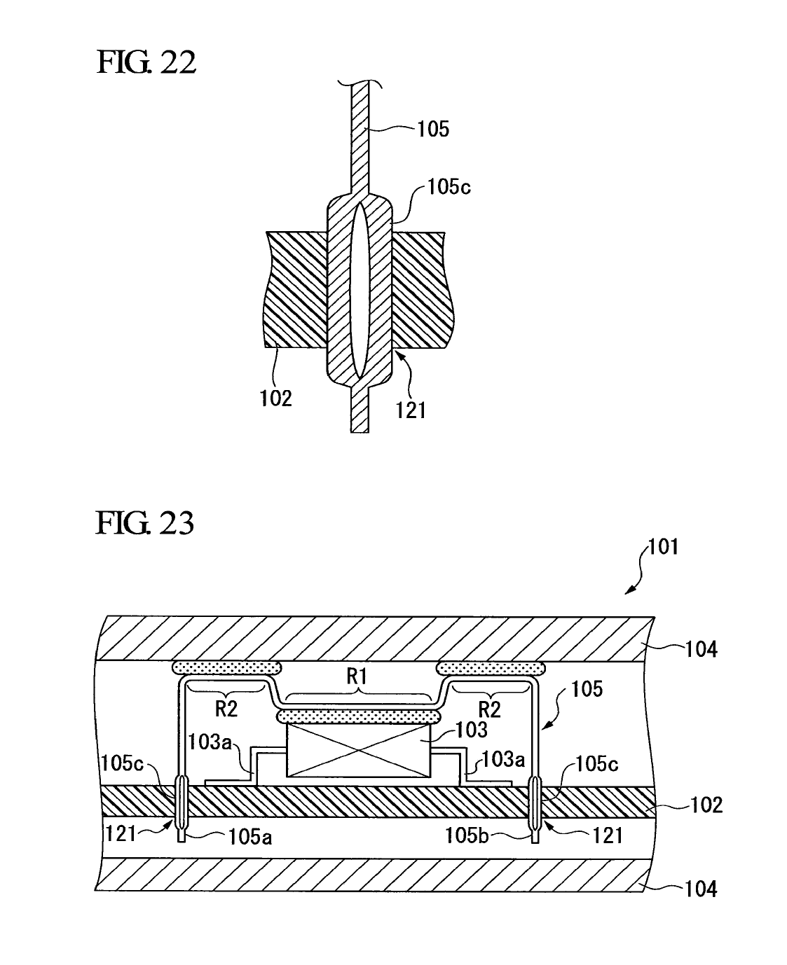

Such press-fit bus-bar 105 is press-fit connected with the printed circuit board 102. Therefore, the positioning of the press-fit bus-bar 105 can be adjusted, by applying force thereto and repositioning it in the thickness direction of the printed circuit board 102, i.e., the insertion direction of the press-fit bus-bar 105. As shown in FIG. 22, the connection part 105c is constituted to have a length longer than the thickness of the printed circuit board 102, in order to maintain a preferable range of positioning adjustment of the press-fit bus-bar 105 in relation to the printed circuit board 102.

Although in FIG. 22 and other figures, the connection part 105c is shown in a so-called eyelet-shape, other constitutions such as sigma-shape, M-shape, ring, or circle shape may also be used.

In the electronic control device 101 having the aforementioned constitution, the heat generated from the heat-generating member 103 is transferred to the casing 104 via the press-fit bus-bar 105, and then radiated to the outside.

In the electronic control device 101 according to the present embodiment, the heat generated from heat-generating member 103 is transferred to the casing 104. Accordingly, the heat generated from heat-generating member 103 can be radiated to the outside.

Moreover, the press-fit bus-bar 105 is press-fit connected with the printed circuit board 102. Accordingly, the press-fit bus-bar 105 can be repositioned in the connection direction with respect to the printed circuit board 102.

In other words, in the electronic control device 101 according to the present embodiment, the positioning of the press-fit bus-bar 105 in the connection direction can be arbitrarily adjusted. Thereby, the press-fit bus-bar 105 for heat transfer can be securely contacted with the heat-generating member 103. Accordingly, even when the preciseness in dimensions of the constituent members of the electronic control device 101 is not sufficiently high, the heat generated from the heat-generating member 103 can be transferred to the casing 104. Therefore, the degree of preciseness in dimensions required for each of the constituent members of the electronic control device 101 can be lowered.

Moreover, during the assembly of the electronic control device 101, even when force is exerted on the press-fit bus-bar 105 from the connection direction, since the press-fit bus-bar 105 is press-fit connected to the printed circuit board 102, the press-fit bus-bar 105 can be repositioned in response to the exerted force, and the stress on the heat-generating member 103 can be reduced.

Accordingly, in the electronic control device 101 according to the present embodiment, the heat generated from heat-generating member 103 can be radiated to the outside. In addition, the stress exerted on the heat-generating member 103 can be reduced, and the required degree of preciseness in dimensions for each of the constituent members of the electronic control device 101 can be safely lowered.

Moreover, in the electronic control device 101 according to the present embodiment, the heat-generating member contact region R1 of the press-fit bus-bar 105 contacts with the heat-generating member 103 along the entire width of the heat-generating member 103.

Accordingly, heat is transferred through the entire width of the heat-generating member 103 to the press-fit bus-bar 105, resulting in an efficient heat radiation.

In the electronic control device 101 according to the present embodiment, as shown in FIG. 23, the heat-generating member contact region R1 of the press-fit bus-bar 105 may contact with heat-generating member 103 via the soft heat transfer member 106 such as silicon gel, grease, or heat transfer sheet. Similarly, the casing contact region R2 may contact with the casing 104 via such soft heat transfer member 106.

By adopting such constitution, deformation of soft heat transfer member 106 absorbs the force exerted from the casing 104 on the heat-generating member 103, and thereby, the stress on the heat-generating member 103 can be reduced.

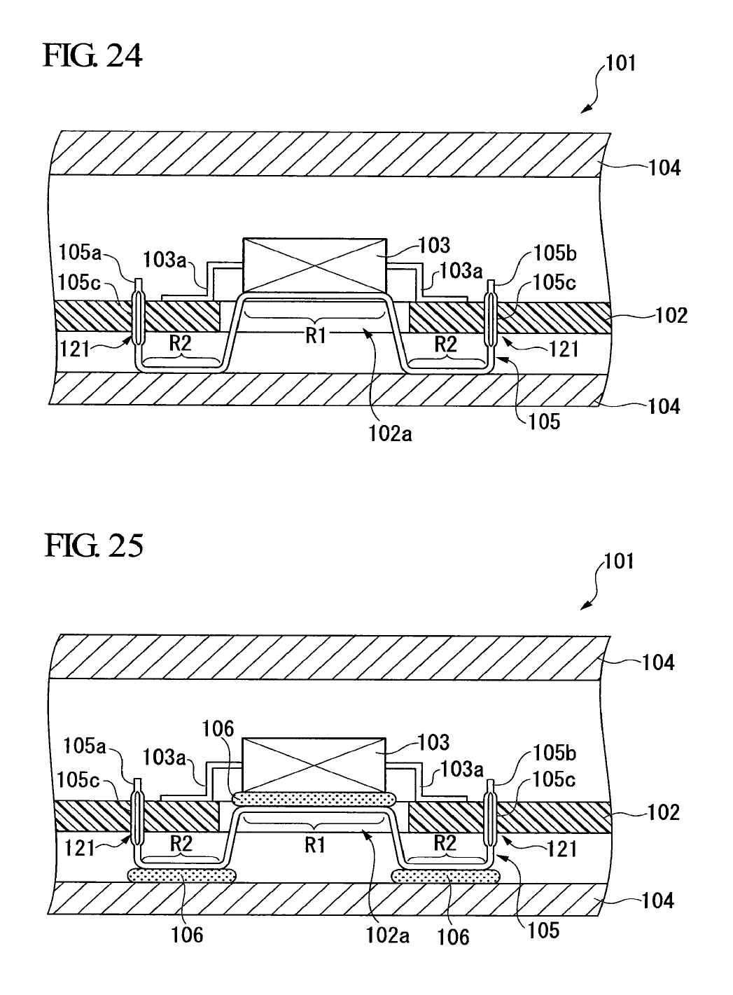

Moreover, in the electronic control device 101 according to the present embodiment, as shown in FIG. 24, an opening 102a may be provided on the printed circuit board 102, and a part of the press-fit bus-bar 105 may be inserted through the opening 102a, and the heat-generating member contact region R1 may contact with the heat-generating member from the side facing the printed circuit board 102 (lower side) thereof.

By adopting such constitution, for example, even in a case where sufficient installation space for press-fit bus-bar 105 can not be obtained above the heat-generating member 103, the press-fit bus-bar 105 may be installed.

Moreover, in the electronic control device 101 according to the present embodiment, as shown in FIG. 25, in addition to the constitution shown in FIG. 24, the heat-generating member contact region R1 of the press-fit bus-bar 105 may further contact with the heat-generating member 103 via the soft heat transfer member 106 such as silicon gel, grease, or heat transfer sheet. Similarly, the casing contact region R2 may contact with the casing 104 via such soft heat transfer member 106.

By adopting such constitution, deformation of soft heat transfer member 106 absorbs the force exerted from the casing 104 on the heat-generating member 103, and thereby, the stress on the heat-generating member 103 can be reduced.

Moreover, in the electronic control device 101 according to the present embodiment, as shown in FIG. 26, a heat transfer passage 102b (heat transfer member) may be provided, that transfers the heat generated from the heat-generating member 103 to the surface opposite from the mounting surface of the heat-generating member 103. In addition, the heat-generating member contact region R1 of the press-fit bus-bar 105 may be abutted on the printed circuit board 102 on the surface opposite from the mounting surface of the heat-generating member 103. That is, the heat-generating member contact region R1 of the press-fit bus-bar 105 may contact with the heat-generating member 103 via the heat transfer passage 102b provided on the printed circuit board 102.

By adopting such constitution, heat accumulated on the printed circuit board 102 may also be reduced.

As shown in FIGS. 23 and 25, in the electronic control device 101 according to the present embodiment, heat-generating member contact region R1 may contact with the heat-generating member 103 via heat transfer member. In addition, the casing contact region R2 may also contact with the casing 104 via the heat transfer member.

### Fourth Embodiment

Next, the fourth embodiment of the present invention is explained. In the explanation of the fourth embodiment, descriptions for similar parts with the aforementioned third embodiment are omitted or simplified.

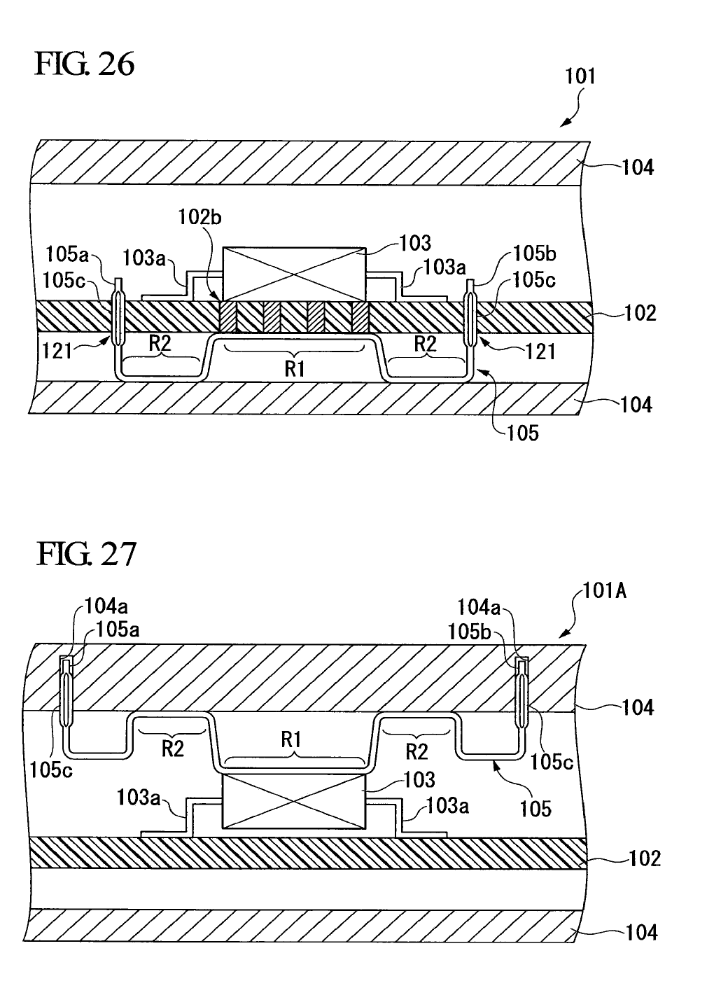

FIG. 27 is a sectional view schematically showing a part of the electronic control device 101A according to the present embodiment. As shown in the figure, in the electronic control device 101A according to the present embodiment, the press-fit bus-bar 105 is press-fit connected with the casing 104, instead of being connected with the printed circuit board 102.

More particularly, an insertion opening 104a is provided on the casing 104. By inserting the connection part 105c of the press-fit bus-bar 105 into the insertion opening 104a, the press-fit bus-bar 105 is press-fit connected to the casing 104.

In the electronic control device 101A according to the present embodiment having the aforementioned constitution, during the assembly of the electronic control device 101A, even when force is exerted on the press-fit bus-bar 105 along the connection direction, since the press-fit bus-bar 105 is press-fit connected with the casing 104, the press-fit bus-bar 105 can reposition in response to the force exerted, and thereby, a stress on the heat-generating member 103 can be controlled.

Accordingly, in the electronic control device 101A according to the present embodiment, as in the case for the electronic control device 101, the heat generated from heat-generating member 103 can be radiated to outside. The stress exerted on the heat-generating member can be reduced, and also the required degree of preciseness in dimensions of each constituent member may be safely lowered.

In the electronic control device 101A according to the present embodiment, as shown in FIG. 28, the heat-generating member contact region R1 of the press-fit bus-bar 105 can be connected to the casing 104 via the soft heat transfer member 106 such as silicon gel, grease, or heat transfer sheet. Similarly, the casing contact region R2 may contact with the casing 104 via such soft heat transfer member 106.

By adopting such constitution, deformation of soft heat transfer member 106 absorbs the force exerted from the casing 104 on the heat-generating member 103, and thereby, the stress on the heat-generating member 103 can be reduced.

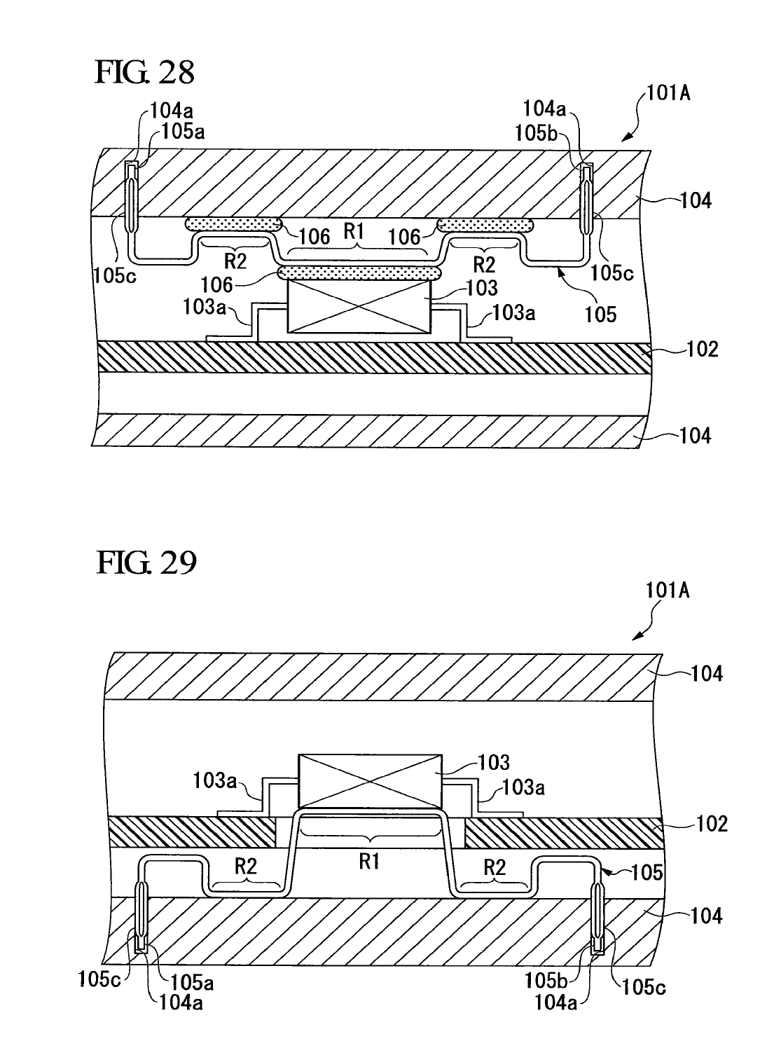

Moreover, in the electronic control device 101 according to the present embodiment, as shown in FIG. 29, an opening 102a may be provided on the printed circuit board 102, and a part of the press-fit bus-bar 105 may be inserted through the opening 102a, and the heat-generating member contact region R1 may contact with the heat-generating member from the side facing the printed circuit board 102 (lower side) thereof.

By adopting such constitution, for example, even in a case where sufficient installation space for press-fit bus-bar 105 can not be obtained above the heat-generating member 103, the press-fit bus-bar 105 may be installed.

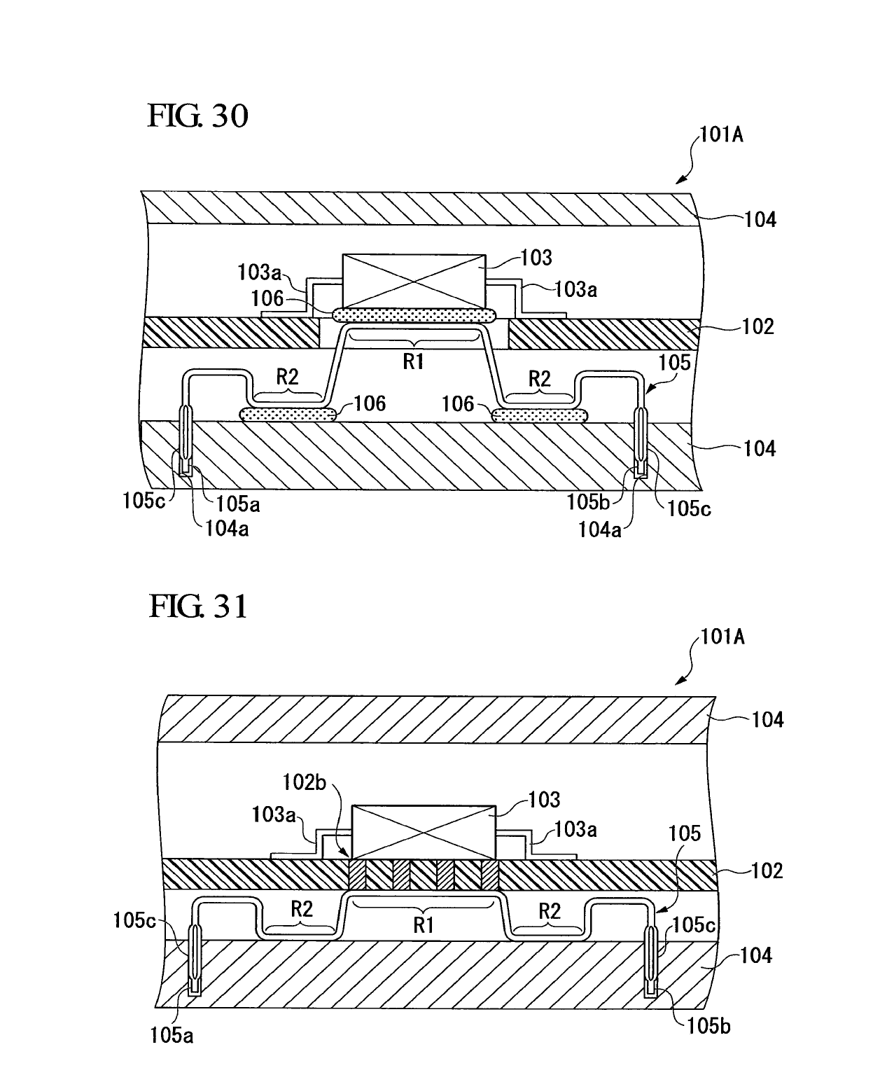

Moreover, in the electronic control device 101A according to the present embodiment, as shown in FIG. 30, in addition to the constitution shown in FIG. 29, the heat-generating member contact region R1 of the press-fit bus-bar 105 may further contact with the heat-generating member 103 via the soft heat transfer member 106 such as silicon gel, grease, or heat transfer sheet. Similarly, the casing contact region R2 may contact with the casing 104 via such soft heat transfer member 106.

By adopting such constitution, deformation of soft heat transfer member 106 absorbs the force exerted from the casing 104 on the heat-generating member 103, and thereby, the stress on the heat-generating member 103 can be reduced.

Moreover, in the electronic control device 101A according to the present embodiment, as shown in FIG. 31, a heat transfer passage 102b (heat transfer member) may be provided, that transfers the heat generated from the heat-generating member 103 to the surface opposite from the mounting surface of the heat-generating member 103. In addition, the heat-generating member contact region R1 of the press-fit bus-bar 105 may be abutted on the printed circuit board 102 on the surface opposite from the mounting surface of the heat-generating member 103. That is, the heat-generating member contact region R1 of the press-fit bus-bar 105 may contact with the heat-generating member 103 via the heat transfer passage 102b provided on the printed circuit board 102.

By adopting such constitution, heat accumulated on the printed circuit board 102 may also be reduced.

The preferable embodiments of the electronic control device according to the present invention are explained hereinabove, with reference to the attached figures. However, the scope of the present invention is not limited by the aforementioned embodiments. The constitutions and the combinations of the constituent members shown in each of the aforementioned embodiments are presented as examples, and the constitutions can be modified within the range not exceeding the essence of the present invention, various modifications are possible, in view of the design requirements and the like.

For example, in the aforementioned embodiments, for the press-fit member of the present invention, the adapted constitution included the press-fit bus-bar 105 having bends between the one end 105a and the another end 105b.

However, the present invention is not limited thereto. The present invention may also adopt an alternative constitution including heat-generating member contact region R1 and the casing contact region R2 that contacts with the casing, and further including any other members as the press-fit member that is press-fit connected to either the printed circuit board 102 or the casing 104.

For example, the width of the heat-generating member contact region R1 and the width of the casing contact region R2 may be different.

In addition, the heat-generating member contact region R1 may be constituted so as to have a circular or an oval shape in plan view. Moreover, the material of the heat-generating member contact region R1 and the material of the casing contact region R2 may be different. Furthermore, the invention may adopt an alternative constitution including further more number of connection part 105c that are press-fit connected with either the printed circuit board 102 or the casing 104.

Moreover, the aforementioned embodiments each included a single press-fit member 105.

However, the present invention is not limited thereto, but may adopt a constitution including a plurality of press-fit member 105.

For example, in a case wherein a plurality of heat-generating members 103 are mounted on the printed circuit board 102, a press-fit member 105 may be provided for each of the heat-generating members 103, so that the constitution includes a plurality of press-fit members 105.

Moreover, to each unit of heat-generating member 103, a plurality of press-fit members 105 may be provided.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. An electronic control device comprising:
a printed circuit board;
a heat-generating member having a plurality of legs which are mounted on the printed circuit board by connections between the legs and the printed circuit board; and
a casing which radiates heat that is transferred from the heat-generating member, wherein:
the legs are connected via press-fit connections with the printed circuit board.

2. The electronic control device according to claim 1, wherein at least one of the legs is a lead that electrically connects the heat-generating member and the printed circuit board.

3. The electronic control device according to claim 1, wherein at least one of the legs is a dummy lead that connects the heat-generating member and the printed circuit board without an electric connection.

4. The electronic control device according to claim 1, further comprising a heat transfer member that transfers heat generated from the heat-generating member to the casing.

5. The electronic control device according to claim 1, wherein the legs are connected via press-fit connections with the printed circuit board and with the casing.

6. An electronic control device comprising:
a printed circuit board on which a heat-generating member is mounted;
a casing that accommodates the printed circuit board; and
a press-fit member having a heat-generating member contact region that contacts with the heat-generating member, and a casing contact region that contacts with the casing, wherein:
the press-fit member is press-fit connected with the printed circuit board or the casing; and
the press-fit member transfers heat generated from the heat-generating member.

7. The electronic control device according to claim 6, wherein:
the press-fit member has a first end and a second end that are press-fit connected to the printed circuit board or the casing; and
the heat-generating member contact region and the casing contact region are provided between the first end and the second end.

8. The electronic control device according to claim 6, wherein the heat-generating member contact region contacts with the heat-generating member via a heat transfer member.

9. The electronic control device according to claim 6, wherein the casing contact region contacts with the casing via a heat transfer member.

10. The electronic control device according to claim 6, wherein a contact region of the heat-generating member contact region that contacts with the heat-generating member spans an entire width of the heat-generating member.
